(19) United States
(12) Patent Application Publication
(10) Pub. No.: US 2012/0057284 A1
(43) Pub. Date: Mar. 8, 2012

(54) COMPUTER ENCLOSURE

(75) Inventors: CHUNG-CHI HUANG, Tu-Cheng (TW); HAI-QING ZHOU, Shenzhen (CN)

(73) Assignees: HON HAI PRECISION INDUSTRY CO., LTD., Tu-Cheng (TW); HONG FU JIN PRECISION INDUSTRY (ShenZhen) Co., LTD, Shenzhen City (CN)

(21) Appl. No.: 12/967,056

(22) Filed: Dec. 14, 2010

(30) Foreign Application Priority Data
Sep. 3, 2010 (CN) 201020516470.0

(51) Int. Cl. G06F 1/16; H05K 5/02

(52) U.S. Cl. 361/679.02; 312/223.2

(57) ABSTRACT

A computer enclosure includes a side panel, and a number of rolling assemblies mounted on the side panel. When the rolling assemblies contact a surface, the computer enclosure can be moved with rolling of the rolling assemblies on the surface.

### BACKGROUND

1. Technical Field

The present disclosure relates to a computer enclosure.

2. Description of Related Art

Some computers come with a large metal enclosure and are heavy, and therefore difficult to move about at need.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of a computer enclosure, in accordance with an embodiment, the computer enclosure including a plurality of rolling assemblies.

FIG. 2 is a partially exploded, isometric view of the computer enclosure of FIG. 1.

FIG. 3 is an exploded, isometric view of one of the rolling assemblies of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

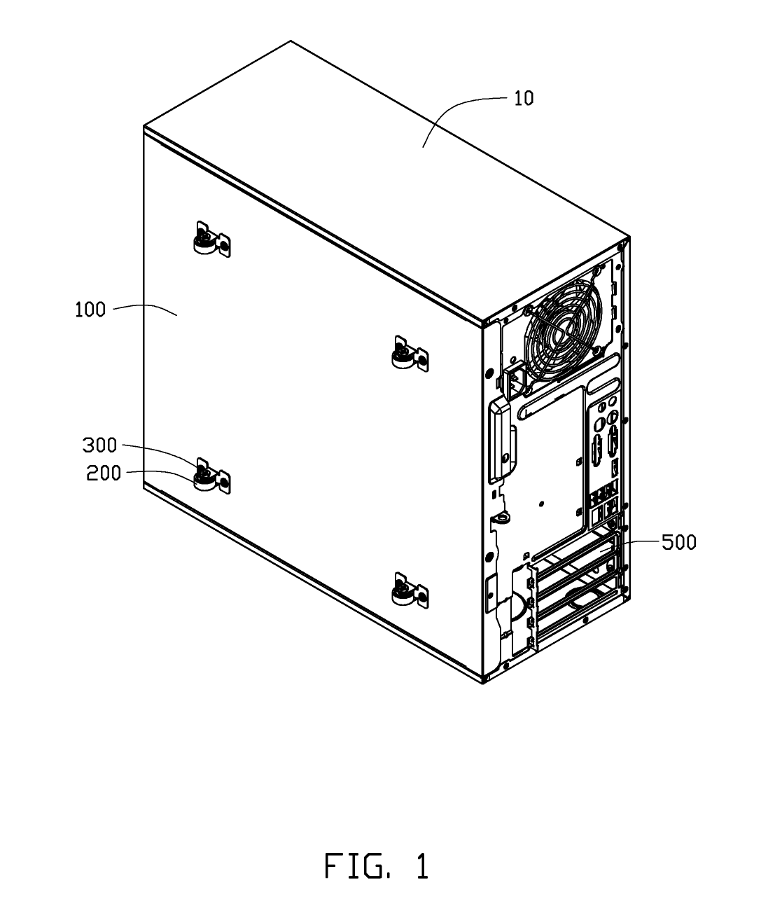

Referring to FIG. 1, an embodiment of a computer enclosure 10 includes a side panel 100, and a plurality of rolling assemblies 200 mounted on the side panel 100. In one embodiment, the side panel 100 has a rectangular configuration, and there are four rolling assemblies 200 mounted on four corners of the side panel 100. In other embodiments, the shape of the side panel 100 and the number of the rolling assemblies 200 can be adjusted according to actual need. The computer enclosure 10 encloses a plurality of electronic components (not shown), such as a motherboard 500 mounted in the computer enclosure 10 opposite to the side panel 100.

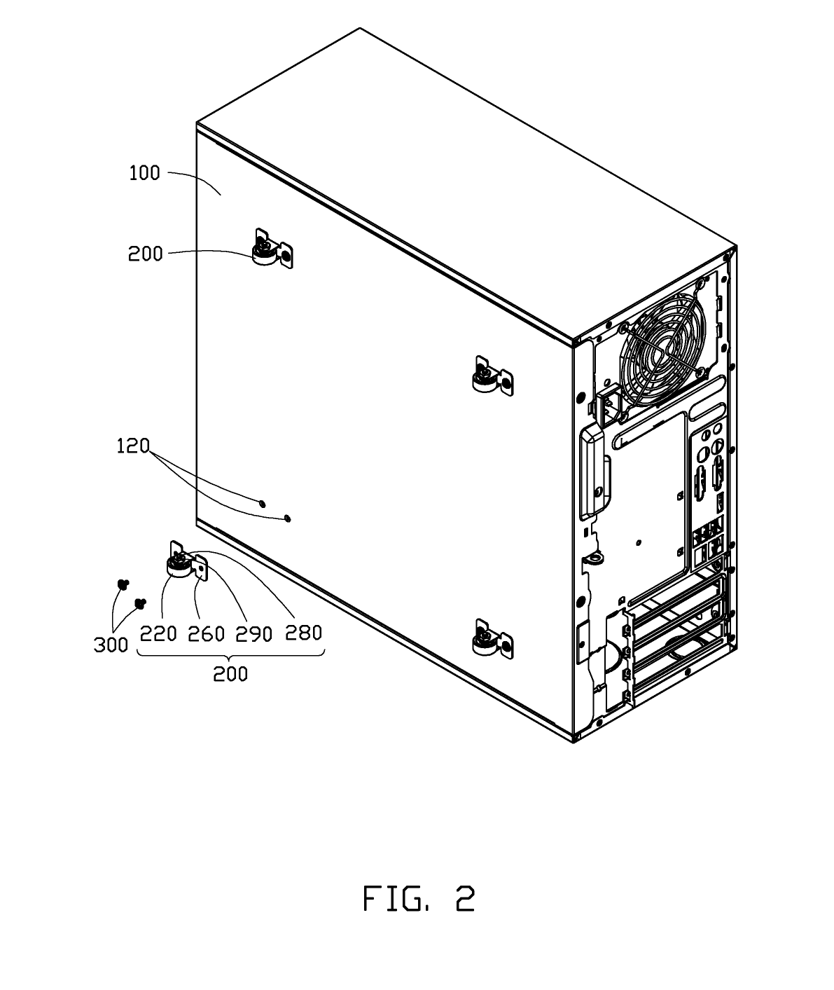

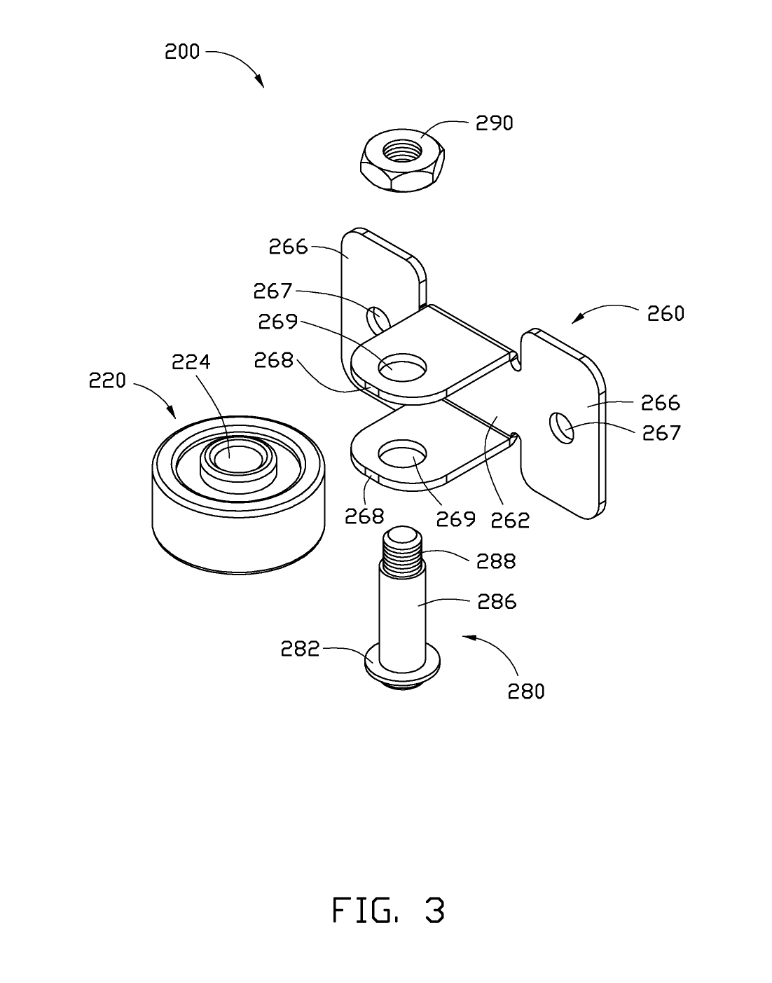

Referring to FIGS. 2 and 3, each rolling assembly 200 includes a wheel 220, a mounting bracket 260, a fastener 280, and a nut 290. The wheel 220 axially defines a through hole 224. The mounting bracket 260 includes a base plate 262, two mounting portions 266 extending from opposite ends of the base plate 262 and coplanar with the base plate 262, and two supporting portions 268 substantially perpendicularly extending from opposite sides of the base plate 262. Each supporting portion 268 defines a mounting hole 269, and the two mounting holes 269 of the two supporting portions 268 align with each other. The fastener 280 includes a shaft 286, a head portion 282, and a threaded portion 288 extending from opposite ends of the shaft 286. The nut 290 can be screwed onto the threaded portion 288 of the fastener 280. In one embodiment, each of the head portion 282, the shaft 286, and the threaded portion 288 is cylindrical, a radius of the shaft portion 286 is less than a radius of the head portion 282, but more than a radius of the threaded portion 288.

In assembly of each rolling assembly 200, the wheel 220 is put between the supporting portions 268, with the through hole 224 aligning with the mounting holes 269. The threaded portion 288 with the shaft 286 of the fastener 280 extends through one of the mounting holes 269, the through hole 224, and the other mounting hole 269, with the head portion 282 of the fastener 280 abutting against the corresponding one of the supporting portion 268. The nut 290 is screwed onto the threaded portion 288 and resists against the other supporting portion 268, to fix the wheel 220 to the mounting bracket 260. The assembled rolling assemblies 200 are then mounted on the side panel 100.

In one embodiment, each mounting portion 266 defines an assembly hole 267, and a plurality of screw holes 120 corresponding to the assembly holes 267 are defined in the side panel 100. A plurality of screws 300 are employed to mount the mounting brackets 260 to the side panel 100. In detail, each screw 300 extends through a corresponding assembly hole 267 and is engaged in a corresponding screw hole 120. Therefore, the assembled rolling assemblies 200 are mounted on the side panel 100 by screws 300. In other embodiments, the assembled rolling assemblies 200 can be mounted on the side panel 100 by other methods, such as welding, and the screw holes 120 and the assembly holes 267 can be omitted according to actual need.

To move the computer enclosure 10, the computer enclosure 10 is set with the wheels 220 of the rolling assemblies 200 contacting a surface, such as the ground, and then can push about on the wheels 220.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A computer enclosure comprising:
a side panel; and
a plurality of rolling assemblies mounted on the side panel;
wherein in response to the rolling assemblies contacting a surface, the computer enclosure can be moved with rolling of the rolling assemblies on the surface.

2. The computer enclosure of claim 1, wherein each rolling assembly comprising:
a wheel axially defining a through hole;
a mounting bracket comprising a base plate, two mounting portions extending from opposite ends of the base plate to be fixed to the side panel, and two supporting portions substantially perpendicularly extending from opposite sides of the base plate, each supporting portion defining a mounting hole, and the two mounting holes of the two mounting portions aligning with each other;
a fastener comprising a shaft, and a head portion and a threaded portion extending from opposite ends of the shaft; and
a nut;
wherein the wheel is put between the supporting portions, with the through hole aligning with the two mounting holes; the threaded portion with the shaft of the fastener extends through one of the mounting holes, the through hole, and the other mounting hole, with the head portion of the fastener abutting against the corresponding one of the supporting portions; and the nut is screwed onto the threaded portion of the fastener and resists against the other supporting portion, to fix the wheel to the mounting bracket.

3. The computer enclosure of claim 2, wherein the mounting portions are coplanar with the base plate.

4. The computer enclosure of claim 1, further comprising a motherboard mounted in the computer enclosure opposite to the side panel.
